(19) United States
(12) Patent Application Publication
(10) Pub. No.: US 2023/0308068 A1
(43) Pub. Date: Sep. 28, 2023

(54) DC TERMINAL MULTI-STAGE FILTER STRUCTURE, MOTOR CONTROLLER AND VEHICLE

(71) Applicant: JEE AUTOMATION EQUIPMENT (SHANGHAI) CO., LTD., Shanghai (CN)

(72) Inventors: Lei LIU, Shanghai (CN); Lingyu ZHU, Shanghai (CN); Yang YANG, Shanghai (CN); Hongxin WU, Shanghai (CN)

(73) Assignee: JEE AUTOMATION EQUIPMENT (SHANGHAI) CO., LTD., Shanghai (CN)

(21) Appl. No.: 18/324,909

(22) Filed: May 26, 2023

Related U.S. Application Data
(63) Continuation of application No. PCT/CN2022/114761, filed on Aug. 25, 2022.

(30) Foreign Application Priority Data
Nov. 15, 2021 (CN) 202111346940.2

(51) Int. Cl. H03H 1/00; H05K 7/14; H01F 27/24; H02G 5/04

(52) U.S. Cl. CPC H03H 1/00; H05K 7/14; H01F 27/24; H02G 5/04; H03H 2001/0021

(57) ABSTRACT

Disclosed are a DC terminal multi-stage filter structure, a motor controller and a vehicle. The DC terminal multi-stage filter structure is fixed on a controller enclosure. A head end of a DC terminal is provided with a high voltage bus and a tail end of the DC terminal is provided with a film capacitor. The DC terminal multi-stage filter structure includes a primary filter holder assembly and a secondary filter holder assembly. The primary filter holder assembly and the secondary filter holder assembly are provided inside the controller enclosure in a line along a length direction of the controller enclosure.

### CROSS-REFERENCE TO RELATED APPLICATIONS

This application is a continuation application of International Application No. PCT/CN2022/114761, filed on Aug. 25, 2022, which claims priority to Chinese Patent Application No. 202111346940.2, filed on Nov. 15, 2021. The disclosures of the above-mentioned applications are incorporated herein by reference in their entireties.

### TECHNICAL FIELD

The present disclosure relates to the technical field of motor controllers, and in particular, to a direct current (DC) terminal multi-stage filter structure, a motor controller with the DC terminal multi-stage filter structure and a vehicle with the motor controller.

### BACKGROUND

Electromagnetic compatibility (EMC) refers to the ability of a device or system to work normally in its electromagnetic environment without producing any unbearable electromagnetic disturbance to other devices in the environment. According to the definition of EMC, electronic equipment must meet the EMC design index. On the one hand, it is necessary to ensure that the electronic equipment has a certain degree of immunity to the electromagnetic interference in the environment. On the other hand, it is required that the electromagnetic interference generated by the electronic equipment during operation must not exceed the specified limit value.

The automotive motor controller is a typical electronic device, on which electronic components such as wiring harnesses, PCBs, power modules, and capacitor modules are laid out. When designing EMC schemes, the general design idea is to add filter components such as magnetic rings and magnetic buckles at the DC terminal and the three-phase terminal, and to add filter capacitors, shielding covers, and grounding designs to the transmission path on the PCB. In order to meet the EMC design index, it's necessary to arrange as many filter devices as possible in a limited space to improve the filtering level.

When designing the DC terminal of the controller in the aspect of EMC, the traditional design method is to add several large and small filter capacitors, magnetic rings, magnetic buckles, filter circuit boards and other filter components on the current transmission path. However, the traditional EMC design method has two disadvantages: on the one hand, since these filter components are independent entities, it is necessary to spare a part of space to fix the components for installation. When there are many filter components, the space for the filter module at the DC terminal of the controller will be enlarged, the design space at the DC/AC terminal will be compressed, and the design difficulty will be significantly increased; on the other hand, the filter components are independent, and the degree of integration of the filter module is low, the installation process is cumbersome, the production cycle of the controller product will be extended, and the production efficiency will be significantly reduced.

### SUMMARY

In response to the above mentioned technical problems, the present disclosure provides a DC terminal multi-stage filter structure, a motor controller and a vehicle. The filter structure adopts a laterally linear layout to integrate and modularize independent filters, mounting bases and current-carrying copper busbars, which can reduce the EMC design space at the DC terminal, simplify the assembly process and improve the assembly efficiency.

The technical solutions of the present disclosure are as follows.

The present disclosure aims to provides a DC terminal multi-stage filter structure fixed on a controller enclosure. A head end of a DC terminal is provided with a high voltage bus and a tail end of the DC terminal is provided with a film capacitor. The DC terminal multi-stage filter structure includes a primary filter holder assembly and a secondary filter holder assembly.

The primary filter holder assembly and the secondary filter holder assembly are provided inside the controller enclosure in a line along a length direction of the controller enclosure. An input end of the high voltage bus is connected with a first positive input end and a first negative input end of the primary filter holder assembly. A first positive output end of the primary filter holder assembly is connected with a second positive input end of the secondary filter holder assembly, and a first negative output end of the primary filter holder assembly is connected with a second negative input end of the secondary filter holder assembly. A second positive output end of the secondary filter holder assembly is connected with a positive input end of the film capacitor, and a second negative output end of the secondary filter holder assembly is connected with a negative input end of the film capacitor.

In some embodiments, the primary filter holder assembly includes a first injection molded shell provided with a first positive copper busbar and a first negative copper busbar; and a first filter provided with a power terminal and a ground terminal. The power terminal overlaps the first positive copper busbar and the first negative copper busbar, and the ground terminal overlaps the controller enclosure;

the secondary filter holder assembly includes a second injection molded shell provided with a second positive copper busbar, a second negative copper busbar and a ground copper busbar. The second positive copper busbar and the second negative copper busbar are parallel in a horizontal direction; and

a second filter including a magnetic ring, a magnetic core, four second Y capacitors, a second X capacitor and a core clamping-plate,

the magnetic core is provided among the four second Y capacitors, a groove is provided on a side of the second injection molded shell close to the primary filter holder assembly, the magnetic ring is fixed in the groove, and the core clamping-plate is fixedly pressed on the magnetic core.

In some embodiments, the primary filter holder assembly further includes a concave structure configured to increase a creepage distance and the concave structure is an injection molded structure, and the second injection molded shell further includes other grooves parallel to the second positive copper busbar and the second negative copper busbar, and the plurality of grooves are configured to accommodate a plurality of filter capacitors.

In some embodiments, the magnetic core includes an E-type core and an I-type core, and/or

the magnetic core is provided with two through holes, and the second positive copper busbar and the second negative copper busbar respectively pass through the two through holes,

a middle part of the magnetic ring is provided with a magnetic ring via-hole, and the second positive copper busbar and the second negative copper busbar pass through the magnetic ring via-hole.

In some embodiments, the magnetic ring is wound from an ultrafine crystalline strip, the magnetic ring is fixed at a side of the second injection molded shell close to the primary filter holder assembly by glue-pouring or glue-dispensing, and/or

the magnetic core is pressed in a groove at a side of the second injection molded shell away from the primary filter holder assembly by the core clamping-plate, the groove at a side of the second injection molded shell away from the primary filter holder assembly is provided with a limiting rib to position the magnetic core, and the core clamping-plate is snap-connected with the secondary filter holder assembly.

In some embodiments, the input end of the high voltage bus is screwed to the first positive input end and the first negative input end of the primary filter holder assembly,

the first positive output end and the first negative output end of the primary filter holder assembly are respectively screwed to the second positive input end and the second negative input end of the secondary filter holder assembly, and

the second positive output end and the second negative output end of the secondary filter holder assembly are respectively screwed to the positive input end of the film capacitor and the negative input end of the film capacitor.

In some embodiments, the first filter includes a circuit board provided with two first X capacitors and two first Y capacitors,

an end of the circuit board close to the high voltage bus is defined with two mounting holes as the power terminal and an end of the circuit board close to the secondary filter holder assembly is defined with a mounting hole as the ground terminal, and

the two first X capacitors are spaced from each other along a direction from the primary filter holder assembly to the secondary filter holder assembly, and the two first Y capacitors are symmetrically provided at both sides of one of the first X capacitors.

In some embodiments, the four second Y capacitors and the second X capacitors are provided in the other grooves of the second injection molded shell by glue-pouring, two of the second Y capacitors are provided at a side of the second injection molded shell away from the primary filter holder assembly side by side, and the other two second Y capacitors and the second X capacitor are provided at a side of the second injection molded shell close to the primary filter holder assembly and close to the magnetic ring,

a power weld leg is introduced from the second positive copper busbar and the second negative copper busbar, and a ground weld leg is introduced from the ground copper busbar, and

the power weld leg is welded together with a power pin of the second X capacitor and a power pin of the second Y capacitors to power up the second X capacitor and the second Y capacitors, and the ground weld leg is welded together with a ground pin of the second Y capacitors to ground the second Y capacitors.

In some embodiments, the controller enclosure includes a shell and a cover,

the shell whose bottom is integrally formed with a shell rib protruding upwardly, and

the cover whose inner top wall is integrally formed with a cover rib protruding downwards,

the shell rib and the cover rib are staggered to form a labyrinth-like shielding cavity, and the primary filter holder assembly and the secondary filter holder assembly are provided inside the labyrinth-like shielding cavity.

The present disclosure further aims to provide a motor controller including one of the above mentioned DC terminal multi-stage filter structures.

The present disclosure further aims to provide a vehicle including the above mentioned motor controller.

Compared with the related art, the advantages of the present disclosure as follows.

The DC terminal multi-stage filter structure of the present disclosure, which collects many filter components together through integration and modularization, can ensure the maximum EMC capability at the DC terminal of the controller in a limited space. In addition, by adding an EMC shielding structure, it can effectively isolate the signal crosstalk between the high and low voltage, reduce space radiation and improve EMC capability.

### BRIEF DESCRIPTION OF THE DRAWINGS

The present disclosure will be briefly described below in conjunction with the accompanying drawings and embodiments.

FIG. 1 is a schematic view of a DC terminal multi-stage filter structure according to some embodiments of the present disclosure.

FIG. 2 is a schematic structural view of a DC terminal multi-stage filter structure mounting on a controller enclosure according to some embodiments of the present disclosure.

FIG. 3 is a schematic structural view of a primary filter holder assembly of a DC terminal multi-stage filter structure according to some embodiments of the present disclosure.

FIG. 4 is a schematic structural view of a first filter of a primary filter holder assembly of a DC terminal multi-stage filter structure according to some embodiments of the present disclosure.

FIG. 5 is a schematic structural view of a secondary filter holder assembly of a DC terminal multi-stage filter structure according to some embodiments of the present disclosure.

FIG. 6 is a schematic structural view of a magnetic ring of a secondary filter holder assembly of a DC terminal multi-stage filter structure according to some embodiments of the present disclosure.

FIG. 7 is a schematic structural view of a magnetic core of a secondary filter holder assembly of a DC terminal multi-stage filter structure according to some embodiments of the present disclosure.

FIG. 8 is a schematic structural view of a shielding cavity of a controller enclosure of a DC terminal multi-stage filter structure according to some embodiments of the present disclosure.

### DETAILED DESCRIPTION OF THE EMBODIMENTS

In order to make the purpose, technical solutions and advantages of the present disclosure clearer, the present disclosure will be further described in detail below in conjunction with specific embodiments and with reference to the accompanying drawings. It should be understood that these descriptions are exemplary only, and are not intended to limit the scope of the disclosure. Also, in the following description, descriptions of well-known structures and techniques are omitted to avoid unnecessarily obscuring the concept of the present disclosure.

As shown in FIG. 1 to FIG. 8, FIG. 1 shows the entire filter topology principle diagram of a DC terminal multi-stage filter structure according to some embodiments of the present disclosure. After the positive and negative poles of the DC terminal pass through the first filter magnetic ring, a filter X capacitor is connected between the positive and negative poles, a filter Y capacitor is connected between the positive pole and ground, a filter Y capacitor is connected between the negative pole and ground, and then the positive and negative poles pass through the second filter magnetic ring. After the second filter magnetic ring pass through the second filter magnetic ring, a filter X capacitor is connected between the positive and negative poles, a filter Y capacitor is connected between the positive pole and ground, and a filter Y capacitor is connected between the positive pole and ground.

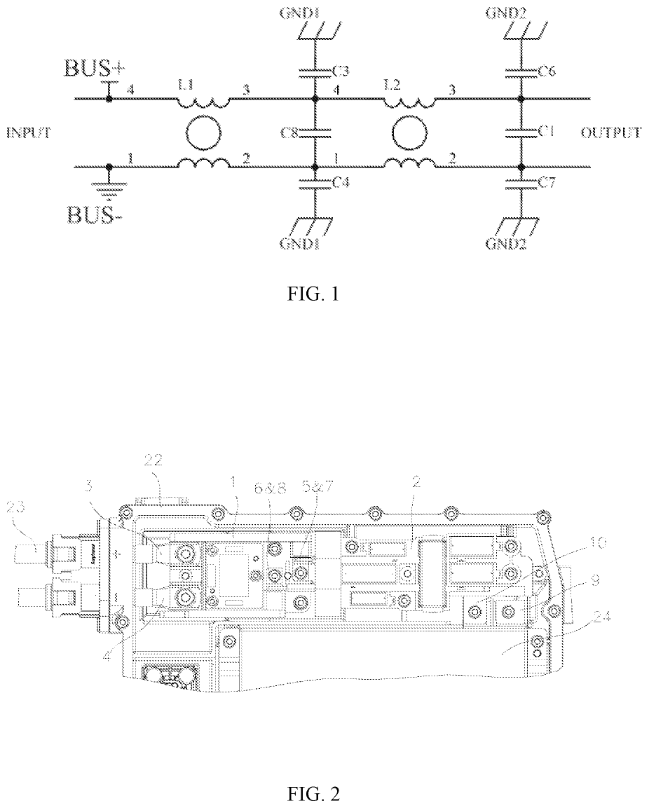

The DC terminal fixed on the controller enclosure refers to the direct current terminal. A head end of the DC terminal that is the left end shown in FIG. 2, is provided with a high voltage bus 23 and a tail end of the DC terminal, that is the right end shown in FIG. 2, is provided with a film capacitor 24. The DC terminal multi-stage filter structure includes a primary filter holder assembly 1 and a secondary filter holder assembly 2. The primary filter holder assembly 1 and the secondary filter holder assembly 2 are provided inside the controller enclosure in a line along a length direction of the controller enclosure. As shown in FIG. 2, the left side of the controller enclosure is provided with the primary filter holder assembly 1, and the right side of the controller enclosure is provided with the secondary filter holder assembly 2, which can well allocate the EMC design space at the DC terminal.

An input end of the high voltage bus 23 is connected with a positive input end and a negative input end of the primary filter holder assembly 1, the positive output end and the negative output end of the primary filter holder assembly 1 are respectively connected with a positive input end and a negative input end of the secondary filter holder assembly 2, and the positive output end and the negative output end of the secondary filter holder assembly 2 are respectively connected with a positive input end of the film capacitor and a negative input end of the film capacitor. In some embodiments, as shown in FIG. 2, the input end of the high voltage bus 23 is screwed to the positive input end and the negative input end of the primary filter holder assembly 1, the positive output end and the negative output end of the primary filter holder assembly 1 are respectively screwed to the positive input end and the negative input end of the secondary filter holder assembly 2, and the positive output end and the negative output end of the secondary filter holder assembly are respectively screwed to the positive input end of the film capacitor and the negative input end of the film capacitor.

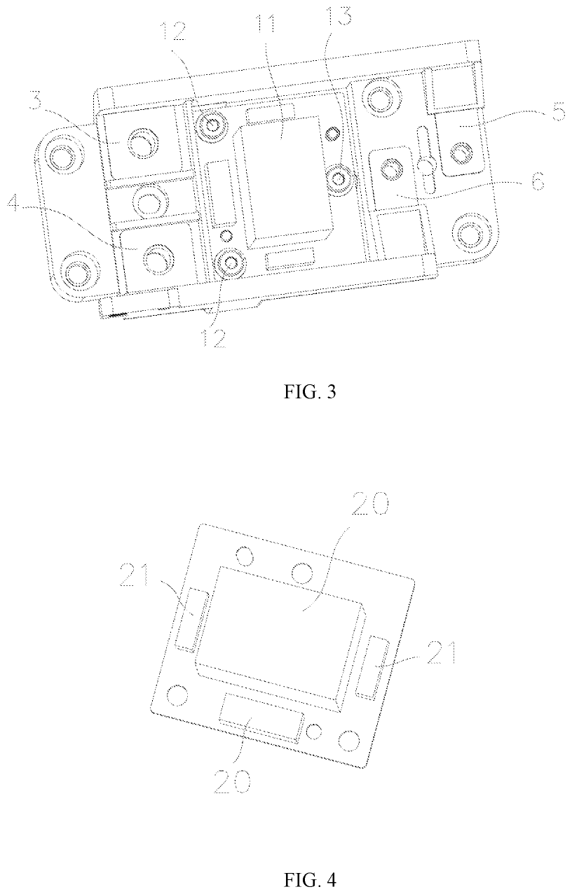

As shown in FIG. 3 and FIG. 4, the primary filter holder assembly 1 includes a first injection molded shell, a first filter 11 and a concave structure (not shown). The first injection molded shell is roughly rectangular. The first injection molded shell is provided with a first positive copper busbar and a first negative copper busbar. Two ends of the first positive copper busbar are respectively configured as the positive input end and the positive output end of the primary filter holder assembly 1, and two ends of the first negative copper busbar are respectively configured as the negative input end and the negative output end of the primary filter holder assembly 1. The concave structure is an injection molded structure and is configured to increase a creepage distance between the first positive copper busbar and the first negative copper busbar. For ease of description and distinction, the positive input end and the positive output end of the primary filter holder assembly are respective described as a first positive input end 3 and a first positive output end 5, and the negative input end and the negative output end of the primary filter holder assembly are respective described as a first negative input end 4 and a first negative output end 6. As shown in FIG. 3, the first positive input end 3 and the first negative input end 4 are provided at the left side of the first injection molded shell side by side, and the first positive output end 5 and the first negative output end 6 are provided at the right side of the first injection molded shell side by side.

As shown in FIG. 3, the first filter 11 is provided among the first positive input end 3, the first negative input end 4, the first positive output end 5 and the first negative output end 6. The first filter 11 includes a circuit board provided with two first X capacitors 20 and two first Y capacitors 21. In these embodiments, the circuit board is a filter printed circuit board (PCB).

As shown in FIG. 4, the two first X capacitors 20 are spaced from each other along a direction from the primary filter holder assembly 1 to the secondary filter holder assembly 2. The two first Y capacitors 21 are symmetrically provided at both sides of one of the first X capacitors 20 which is close to the first positive output end 5 or the first negative output end 6. In some embodiments, the circuit board is square. The larger first X capacitor 20 is provided on the upper right side of the circuit board and the smaller first X capacitor 20 spaced from another first X capacitor 20, is provided on the lower left side of the circuit board. The two first Y capacitors 21 are symmetrically provided at both sides of the larger first X capacitor 20. The circuit board is defined with three mounting holes. Two of the mounting holes provided on both sides of the smaller first X capacitor 20 are configured as the power terminal 12, and the mounting hole provided on an upper right side of the larger first X capacitor 20 is configured as the ground terminal 13. The power terminal 12 overlaps the first positive copper busbar and the first negative copper busbar to power up two poles of the second X capacitor 20 and one pole of the second Y capacitor 21. The ground terminal 13 overlaps the controller enclosure to power up the other pole of the Y capacitor 21. The second X capacitor 20 can effectively suppress differential mode interference, and the first Y capacitor 21 can effectively suppress common mode interference.

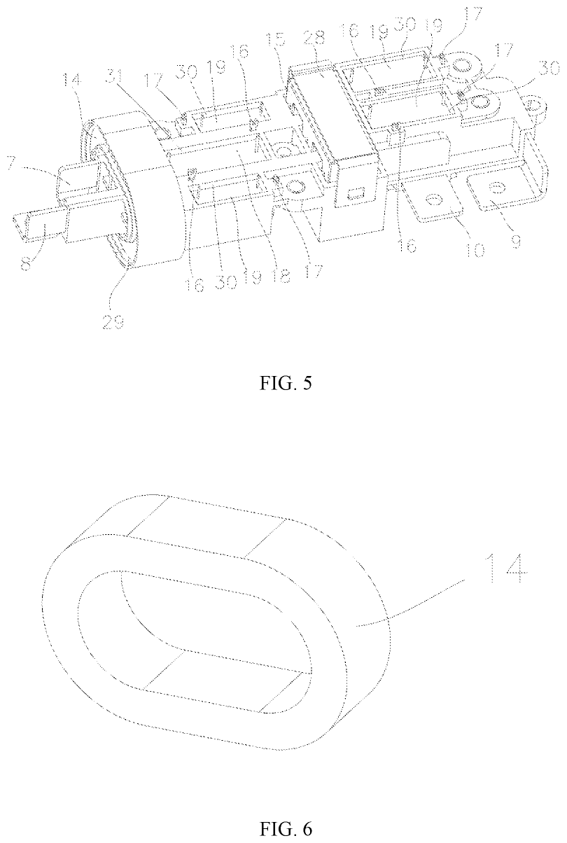

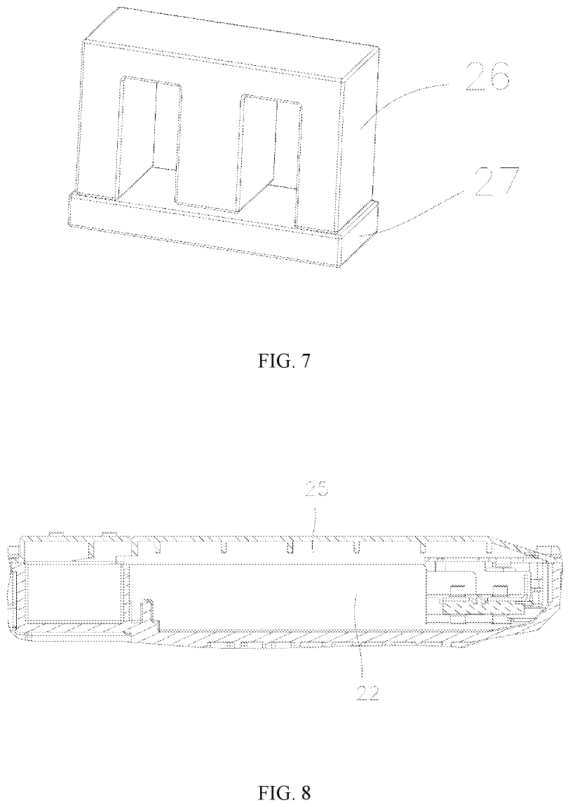

As shown in FIG. 5 and FIG. 7, the secondary filter holder assembly 2 includes a second injection molded shell and a second filter. The second injection molded shell extends laterally, that is to say, as shown in FIG. 2, the second injection molded shell extends in the left and right direction. The second injection molded shell is provided with a second positive copper busbar, a second negative copper busbar, a ground copper busbar and a plurality of grooves 30, 31. For ease of description and distinction, the positive input end and the positive output end of the secondary filter holder assembly 2 are respective described as a second positive input end 7 and a second positive output end 9, and the negative input end and the negative output end of the secondary filter holder assembly 2 are respective described as a second negative input end 8 and a second negative output end 10. The plurality of grooves 30, 31 are parallel to the second positive copper busbar and the second negative copper busbar. The plurality of grooves 30, 31 are configured to accommodate a plurality of filter capacitors. By adding or deleting filter capacitors, the filter structure can meet different requirements such as EMC level 3, level 4, and level 5. As shown in FIG. 5, the second positive input end 7 and the second negative input end 8 are provided side by side on the left side of the second injection molded shell, and the second positive output end 9 and the second negative output end 10 are provided side by side on right front end of the second injection molded shell.

The second filter includes a magnetic ring 14, a magnetic core 15, four second Y capacitors 19, a second X capacitor 18 and a core clamping-plate 28. As shown in the FIG. 5, the oval magnetic ring 14 is provided with a via-hole in the middle, and the second positive copper busbar and the second negative copper busbar pass through the via-hole. As shown in FIG. 5, the magnetic ring 14 is fixed in a groove 29 of the second injection molded shell at a side close to the primary filter holder assembly 1, the groove 29 is the left one in FIG. 5. The groove 29 is an oval groove matching the magnetic ring 14.

The magnetic core 15 is pressed on the second injection molded shell by the core clamping-plate 28. The magnetic core 15 is provided with two through holes (not shown), and the second positive copper busbar and the second negative copper busbar respectively pass through the two through holes, which can effectively suppress differential mode or common mode interference. In addition, the magnetic core 15 is fixed by the core clamping-plate 28, which can reduce the performance loss of the magnetic core. As shown in FIG. 7, the magnetic core 15 includes an E-type core 26 and an I-type core 27. The E-type core 26 opening facing downwards is fixed on the I-type core 27.

As shown in FIG. 5, the core clamping-plate 28 is made from metal materials such as copper, aluminum and other materials, and the core clamping-plate 28 is a U-shaped structure whose both sides walls of the opening are provided with buckles or slots. Correspondingly, the secondary filter holder assembly 2 is provided with the corresponding slots or buckles. The bottom wall of the core clamping-plate 28 is fixed on the upper surface of the magnetic core 15 by glue-pouring. In some embodiments, the core clamping-plate 28 and the secondary filter holder assembly 2 can also be fixed in other ways, such as screw fixing, etc., which are not limited in detail. Those skilled in the art can select a design according to actual needs, and in these embodiments, clamping is adopted for fixing. In some embodiments, the groove of the secondary filter holder assembly 2 is provided with a limiting rib to position, thereby to limit the top side and lateral sides of the magnetic core 15. The core clamping-plate 28 may limit the bottom side of the magnetic core 15, such that the location of the magnetic core 15 is completely limited horizontally and vertically. The specific structure of the limiting ribs is not described and limited in detail, and can be designed according to the bottom structure of the magnetic core 15.

The four second Y capacitors 19 and the second X capacitors 18 are provided in the other grooves 30, 31 of the second injection molded shell by glue-pouring. In some embodiments, as shown in FIG. 5, two of the second Y capacitors 19 are provided at a side of the second injection molded shell away from the primary filter holder assembly 1 side by side, and the other two second Y capacitors 19 and the second X capacitor 18 are provided at a side of the second injection molded shell close to the primary filter holder assembly 1 and close to the magnetic ring 14. As shown in FIG. 5, the side of the second injection molded shell close to the primary filter holder assembly 1 and close to the magnetic ring 14 refer to the left side of the second injection molded shell and the right side of the magnetic ring 14.

As shown in FIG. 5, the magnetic core 15 is provided among the four second Y capacitors 19 and at the center of the second injection molded shell.

A power weld leg 16 is introduced from the second positive copper busbar and the second negative copper busbar, and a ground weld leg 17 is introduced from the ground copper busbar, and the power weld leg 16 is welded together with a power pin of the second X capacitor 18 and a power pin of the second Y capacitors 19 to power up the second X capacitor 18 and the second Y capacitors 19. The ground weld leg 17 is welded together with a ground pin of the second Y capacitors 19 to ground the second Y capacitors 19. The second X capacitor 18 can effectively suppress differential mode interference, and the second Y capacitor 19 can effectively suppress common mode interference.

In some embodiments, the magnetic ring 14 is fixed at a side of the second injection molded shell close to the primary filter holder assembly 1 by glue-pouring or glue-dispensing, that is to say, as shown in FIG. 5, the magnetic ring 14 is located at the left side of the second injection molded shell. In some alternative embodiments, the magnetic ring 14 can also be fixed by a stainless steel shrapnel and a silicone cushion.

In some embodiments, the magnetic core 15 is fixed in a groove at a side of the second injection molded shell away from the primary filter holder assembly 1 by the glue-pouring, that is to say, as shown in FIG. 5, the magnetic core 15 is located in the middle of the second injection molded shell.

It's noted that the applicant had previously applied for a patent on a similar multi-stage filter structure, but the applicant found that improvement is still needed. This disclosure is based on the improvement of the previous disclosure. In addition to the above-mentioned arrangement and structural improvements, there are also some other structural improvements. In some embodiments, as shown in FIG. 8, the controller enclosure includes a shell and a cover. The shell is bent upwards and extended to form a first cavity, and the bottom of the shell is integrally formed with a shell rib 22 protruding upwardly. The shell rib 22 is provided on the front and rear sides of the shell. The cover is bent downward and extended to form a second cavity, and the top wall of the cover is integrally formed with a cover rib 25 protruding downwards. The cover rib 25 is provided at intervals along the length direction of the cover, that is, the left and right direction as shown in FIG. 8. The shell rib 22 and the cover rib 25 are staggered to form a labyrinth-like shielding cavity. The specific structure which is not described and limited here is the shielding structure of the existing conventional labyrinth structure which is known and easily realized by those skilled in the art. The magnetic ring assembly that is the primary filter holder assembly 1 and the secondary filter holder assembly 2, is mounted inside the labyrinth-like shielding cavity. The assembly of EMC shielding protection is completed when the magnetic ring assembly, shell and cover of the DC terminal multi-stage filter structure are assembled, which reduces the assembly process and improves production efficiency.

In the DC terminal multi-stage filter structure according to some embodiments of the present disclosure, the plurality of filter components are integrated together by integration and modularization, which may improve the EMC capacity of the DC terminal of the controller to the greatest extent in a limited space. By adding the EMC shielding structure, the high and low voltage signal crosstalk can be effectively isolated, the space radiation can be reduced, and the EMC capability can be improved. The shielding structure is a labyrinth-like shielding structure formed by the shell rib 22 and the cover rib 25, which may replace the existing metal shielding cover, and does not require an additional shielding structure, and has a simple structure.

In the DC terminal multi-stage filter structure of the embodiments of the present disclosure, a magnetic ring 14 is used to replace the magnetic core at the connection between the primary filter holder assembly 1 and the secondary filter holder assembly 2, such that the primary filter holder assembly 1 and the second filter 2 is combined into one, which can improve the EMC capability of the DC terminal of the controller to the greatest extent in a limited space.

The DC terminal multi-stage filter structure according to some embodiments of the present disclosure can meet the EMC level 3, level 4, Level 5 and other different level requirements.

The present disclosure further provides a motor controller including the DC terminal multi-stage filter structure of the above mentioned embodiments. Other structures and working principles of the motor controller are not described and limited in detail here. Other structures are existing conventional structures.

The present disclosure further provides a vehicle including the motor controller in the above mentioned embodiments.

It should be understood that the above specific implementation manners of the present disclosure are only used to illustrate or explain the principle of the present disclosure, but not to limit the present disclosure. Therefore, any modification, equivalent replacement, improvement, etc. made without departing from the spirit and scope of the present disclosure shall fall within the protection scope of the present disclosure. Furthermore, the claims of this disclosure are intended to embrace all changes and modifications that within the scope or equivalents of such scope.

What is claimed is:

1. A direct current (DC) terminal multi-stage filter structure fixed on a controller enclosure, wherein:
a head end of a DC terminal is provided with a high voltage bus and a tail end of the DC terminal is provided with a film capacitor,
the DC terminal multi-stage filter structure comprises a primary filter holder assembly and a secondary filter holder assembly,
the primary filter holder assembly and the secondary filter holder assembly are provided inside the controller enclosure in a line along a length direction of the controller enclosure,
an input end of the high voltage bus is connected with a first positive input end and a first negative input end of the primary filter holder assembly,
a first positive output end of the primary filter holder assembly is connected with a second positive input end of the secondary filter holder assembly, and a first negative output end of the primary filter holder assembly is connected with a second negative input end of the secondary filter holder assembly, and
a second positive output end of the secondary filter holder assembly is connected with a positive input end of the film capacitor, and a second negative output end of the secondary filter holder assembly is connected with a negative input end of the film capacitor.

2. The DC terminal multi-stage filter structure of claim 1, wherein:
the primary filter holder assembly comprises:
a first injection molded shell provided with a first positive copper busbar and a first negative copper busbar; and
a first filter provided with a power terminal and a ground terminal, the power terminal overlapping the first positive copper busbar and the first negative copper busbar, and the ground terminal overlapping the controller enclosure;
the secondary filter holder assembly comprises:
a second injection molded shell provided with a second positive copper busbar, a second negative copper busbar and a ground copper busbar, the second positive copper busbar and the second negative copper busbar being parallel in a horizontal direction; and
a second filter comprising a magnetic ring, a magnetic core, four second Y capacitors, a second X capacitor and a core clamping-plate,
wherein the magnetic core is provided among the four second Y capacitors, a groove is provided on a side of the second injection molded shell close to the primary filter holder assembly, the magnetic ring is fixed in the groove, and the core clamping-plate is fixedly pressed on the magnetic core.

3. The DC terminal multi-stage filter structure of claim 2, wherein:
the primary filter holder assembly further comprises a concave structure configured to increase a creepage distance and the concave structure is an injection molded structure, and
the second injection molded shell further comprises other grooves parallel to the second positive copper busbar and the second negative copper busbar, and the plurality of grooves are configured to accommodate a plurality of filter capacitors.

4. The DC terminal multi-stage filter structure of claim 2, wherein:
the magnetic core comprises an E-type core and an I-type core, and/or
the magnetic core is provided with two through holes,
the second positive copper busbar and the second negative copper busbar respectively pass through the two through holes,
a middle part of the magnetic ring is provided with a magnetic ring via-hole, and
the second positive copper busbar and the second negative copper busbar pass through the magnetic ring via-hole.

5. The DC terminal multi-stage filter structure of claim 2, wherein:
the magnetic ring is wound from an ultrafine crystalline strip,
the magnetic ring is fixed at a side of the second injection molded shell close to the primary filter holder assembly by glue-pouring or glue-dispensing, and/or
the magnetic core is pressed in a groove at a side of the second injection molded shell away from the primary filter holder assembly by the core clamping-plate,
the groove at a side of the second injection molded shell away from the primary filter holder assembly is provided with a limiting rib to position the magnetic core, and
the core clamping-plate is snap-connected with the secondary filter holder assembly.

6. The DC terminal multi-stage filter structure of claim 1, wherein:
the input end of the high voltage bus is screwed to the first positive input end and the first negative input end of the primary filter holder assembly,
the first positive output end and the first negative output end of the primary filter holder assembly are respectively screwed to the second positive input end and the second negative input end of the secondary filter holder assembly, and
the second positive output end and the second negative output end of the secondary filter holder assembly are respectively screwed to the positive input end of the film capacitor and the negative input end of the film capacitor.

7. The DC terminal multi-stage filter structure of claim 2, wherein:
the first filter comprises a circuit board provided with two first X capacitors and two first Y capacitors,
an end of the circuit board close to the high voltage bus is defined with two mounting holes as the power terminal and an end of the circuit board close to the secondary filter holder assembly is defined with a mounting hole as the ground terminal, and
the two first X capacitors are spaced from each other along a direction from the primary filter holder assembly to the secondary filter holder assembly, and the two first Y capacitors are symmetrically provided at both sides of one of the first X capacitors.

8. The DC terminal multi-stage filter structure of claim 2, wherein:
the four second Y capacitors and the second X capacitors are provided in the other grooves of the second injection molded shell by glue-pouring,
two of the second Y capacitors are provided at a side of the second injection molded shell away from the primary filter holder assembly side by side, and the other two second Y capacitors and the second X capacitor are provided at a side of the second injection molded shell close to the primary filter holder assembly and close to the magnetic ring,
a power weld leg is introduced from the second positive copper busbar and the second negative copper busbar, and a ground weld leg is introduced from the ground copper busbar, and
the power weld leg is welded together with a power pin of the second X capacitor and a power pin of the second Y capacitors to power up the second X capacitor and the second Y capacitors, and
the ground weld leg is welded together with a ground pin of the second Y capacitors to ground the second Y capacitors.

9. The DC terminal multi-stage filter structure of claim 1, wherein:
the controller enclosure comprises:
a shell whose bottom is integrally formed with a shell rib protruding upwardly, and
a cover whose inner top wall is integrally formed with a cover rib protruding downwards,
wherein the shell rib and the cover rib are staggered to form a labyrinth-like shielding cavity, and
the primary filter holder assembly and the secondary filter holder assembly are provided inside the labyrinth-like shielding cavity.

10. A motor controller, comprising the DC terminal multi-stage filter structure of claim 1.

11. A vehicle, comprising the motor controller of claim 10.
